(19) United States
(12) Patent Application Publication
(10) Pub. No.: US 2010/0019303 A1
(43) Pub. Date: Jan. 28, 2010

(54) METHOD FOR FORMING CONDUCTIVE PATTERN, SEMICONDUCTOR DEVICE USING THE SAME AND METHOD FOR FABRICATING SEMICONDUCTOR DEVICE USING THE SAME

(75) Inventor: Jeong-Kyu KANG, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/413,434

(22) Filed: Mar. 27, 2009

(30) Foreign Application Priority Data
Jul. 23, 2008 (KR) 10-2008-0071848

(51) Int. Cl. H01L 29/68; H01L 21/3213; H01L 23/48

(52) U.S. Cl. 257/314; 438/584; 438/669; 257/734; 257/E29.17; 257/E23.01; 257/E21.314

(57) ABSTRACT

A method for fabricating conductive patterns includes forming a conductive layer over a substrate, etching the conductive layer to a first thickness to form first patterns, forming spacers on sidewalls of the first patterns, and etching the conductive layer to a second thickness using the spacers as an etch barrier to form second patterns. Thus, conductive patterns can be formed with vertical sidewalls without being damaged, and lean and collapse of the conductive patterns are prevented.

### CROSS-REFERENCE TO RELATED APPLICATIONS

The present invention claims priority of Korean patent application number 2008-0071848, filed on Jul. 23, 2008, which is incorporated by reference in its entirety.

### BACKGROUND OF THE INVENTION

The present invention relates to a method for forming conductive patterns, a semiconductor device using the same and a method for fabricating a semiconductor device using the same.

During a semiconductor device fabrication process, a conductive patterning technology is required to form line patterns such as a metal line, a gate line, and a bit line. Particularly, as the semiconductor device is highly integrated, line/space width is decreased. Thus, a technology for forming fine conductive patterns is required.

Hereinafter, a conventional conductive pattern process and problem thereof are specifically described.

FIGS. 1A and 1B are cross-sectional views describing a conventional method for forming conductive patterns.

Referring to FIG. 1A, a conductive layer 110 is formed over a substrate 100. Photoresist patterns 120 are formed over the conductive layer 110 to form conductive patterns. Herein, the conductive patterns indicate certain patterns such as a metal line or a bit line formed in the semiconductor device.

Referring to FIG. 1B, the conductive layer 110 is etched using the photoresist patterns 120 as an etch barrier to form conductive patterns 110A. Herein, an etch depth is the same as a thickness W1 of the conductive layer 110. That is, the conductive layer 110 is etched once to form the conductive patterns 110A.

In the conventional process described above, the photoresist patterns 120 may be damaged when the conductive layer 110 is etched. In this case, since the photoresist patterns 120 cannot sufficiently function as an etch barrier, sidewalls of the conductive patterns 110A may be damaged.

Particularly, since the conductive layer 110 is etched once to form the conductive patterns 110A, an upper portion of the conductive patterns 110A may be continuously exposed to an etch gas when a lower portion of the conductive patterns 110A is formed. Thus, the sidewalls of the conductive patterns 110A are damaged and a slope (refer to “A”) is formed. The slope may causes the conductive patterns 110A to lean or collapse.

FIG. 2 is a micrographic view of conductive patterns formed through the conventional process for forming conductive patterns.

As shown, when the conductive layer is etched to form the conductive patterns, the sidewalls of the conductive patterns are damaged and the slope is formed. Furthermore, when the damage is serious, it may cause leaning or collapse of the conductive patterns.

### SUMMARY OF THE INVENTION

Embodiments of the present invention are directed to providing a method for forming conductive patterns, a semiconductor device using the same and a method for fabricating a semiconductor device using the sa me.

In accordance with an aspect of the present invention, a method for fabricating conductive patterns includes forming a conductive layer over a substrate, etching the conductive layer to a first thickness to form first patterns, forming spacers on sidewalls of the first patterns, and etching the conductive layer to a second thickness using the spacers as an etch barrier to form second patterns.

In accordance with another aspect of the present invention, a method for fabricating a semiconductor device includes forming a metal layer over a substrate, etching the metal layer to a first thickness using mask patterns as an etch barrier to form first patterns, forming insulation layer spacers on sidewalls of the first patterns, and etching the metal layer to a second thickness using the mask patterns and the insulation layer spacers as etch barriers to form second patterns.

In accordance with still another aspect of the present invention, a semiconductor device includes conductive patterns including first patterns with spacers formed on sidewalls thereof and second patterns formed to be connected to a lower portion of the first patterns, respectively, wherein the spacers are used as an etch barrier when the second patterns are formed.

### BRIEF DESCRIPTION OF THE DRAWINGS

FIGS. 1A and 1B are cross-sectional views describing a conventional method for forming conductive patterns.

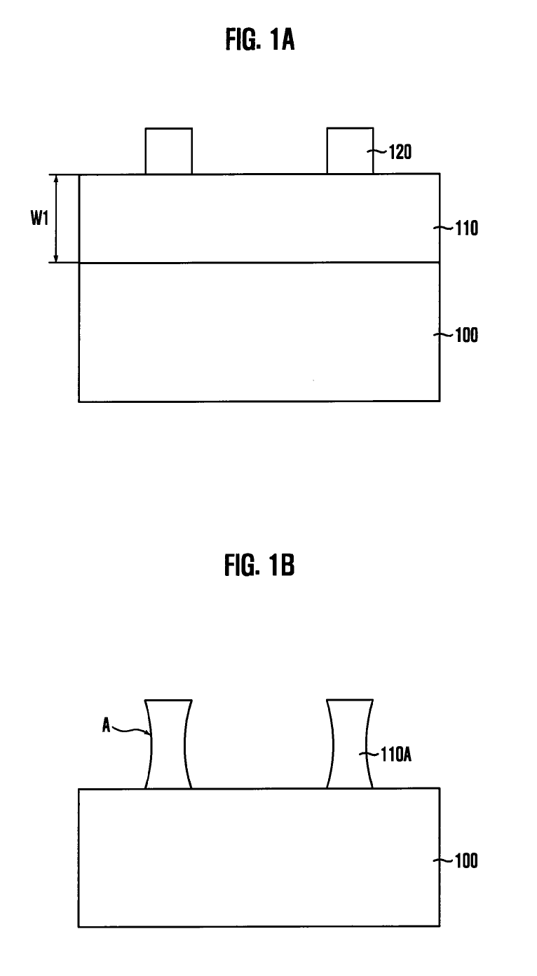

FIG. 2 is a micrographic view of conductive patterns formed through the conventional process for forming conductive patterns.

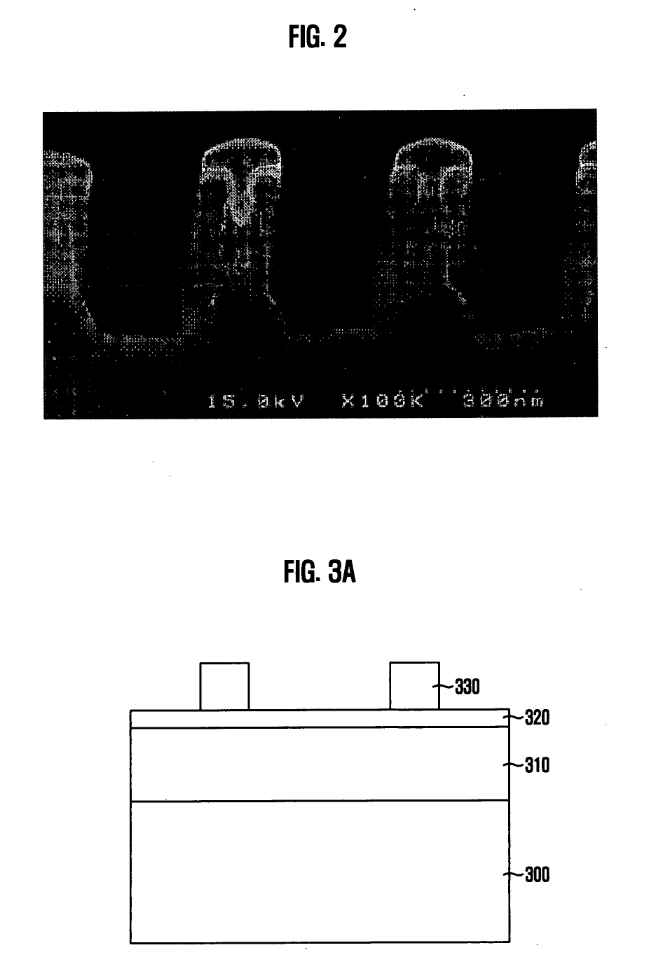

FIGS. 3A to 3C are cross-sectional views of a method for forming conductive patterns in accordance with an embodiment of the present invention.

### DESCRIPTION OF EMBODIMENTS

Embodiments of the present invention relate to a method for forming conductive patterns, a semiconductor device using the same and a method for fabricating a semiconductor device using the same.

Referring to the drawings, the illustrated thickness of layers and regions are exaggerated to facilitate explanation. When a first layer is referred to as being “on” a second layer or “on” a substrate, it could mean that the first layer is formed directly on the second layer or the substrate, or it could also mean that a third layer may exist between the first layer and the second layer/substrate. Furthermore, the same or like reference numerals throughout the various embodiments of the present invention represent the same or like elements in different drawings.

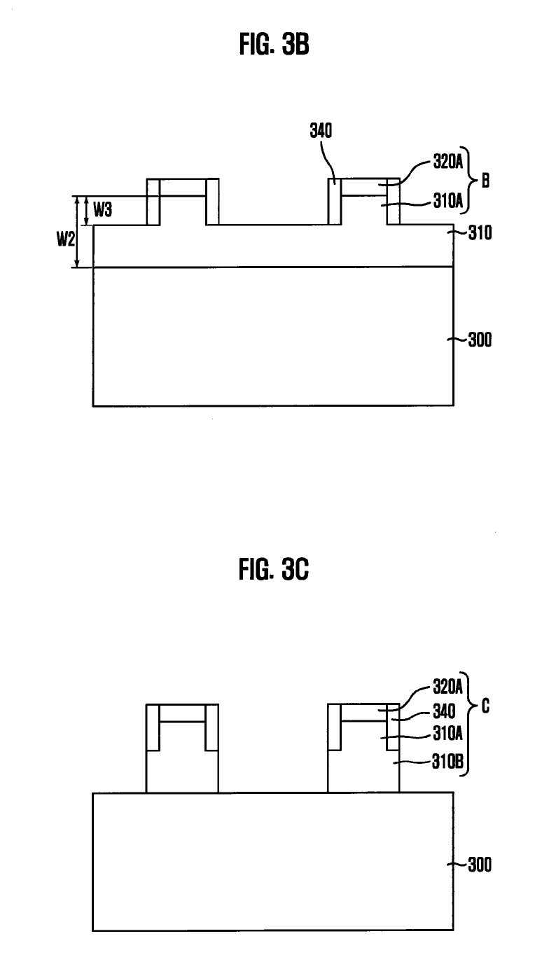

FIGS. 3A to 3C are cross-sectional views of a method for forming conductive patterns in accordance with an embodiment of the present invention.

Referring to FIG. 3A, a conductive layer 310 is formed over a substrate 300. Herein, preferably, the conductive layer 310 includes aluminum (Al), tungsten (W), or copper (Cu).

A hard mask layer 320 is formed over the conductive layer 310. Preferably, the hard mask layer 320 includes an oxide layer. Photoresist patterns 330 are formed over the hard mask layer 320 to form conductive patterns. Herein, the conductive patterns indicate certain patterns such as a gate line or a bit line formed in the semiconductor device.

Referring to FIG. 3B, the hard mask layer 320 may be etched using the photoresist patterns 330 as an etch barrier to form mask patterns 320A. The conductive layer 310 is etched to a predetermined thickness W3 using the mask patterns 320A as an etch barrier to form first patterns B. Herein, preferably, the predetermined thickness W3 ranges from approximately 30% to approximately 40% of a thickness W2 of the conductive layer. Thus, the first patterns B are formed to have a stack structure of the conductive patterns 310A with the predetermined thickness W3 and the mask patterns 320A.

Spacers 340 are formed on sidewalls of the first patterns B. To form the spacers 340, an insulation layer for spacers is formed over a resultant structure including the first patterns B. The insulation layer is spacer etched to form the spacers 340 on the sidewalls of the first patterns B.

Herein, preferably, the spacers 340 include a material having a high selectivity ratio with the hard mask layer 320. Furthermore, preferably, the spacers 340 include a material having a high selectivity ratio with the conductive layer 310. For instance, preferably, the spacers 340 include an oxide layer or a nitride layer.

Referring to FIG. 3C, the conductive layer 310 is further etched using the spacers as an etch barrier to form second patterns 310B. The second patterns 310B are formed to be connected to a lower portion of the first patterns B, respectively. Thus, conductive patterns C are formed to include first patterns B with the spacers formed on the sidewalls thereof and the second patterns 310B.

As described above, when the second patterns 310B are formed, the sidewalls of the conductive patterns 310A having a predetermined thickness are protected by the spacers 340. Thus, when the second patterns 310B are formed, the sidewalls of the conductive patterns 310A are not damaged.

In the conventional process, the conductive layer 310 is etched once. However, in embodiments of the present invention, the predetermined thickness W3 of the conductive layer 310 is etched to form the spacers 340. Then, a remaining portion of the conductive layer 310 is etched to form conductive patterns C. Thus, the sidewalls of the conductive patterns C are not damaged and the conductive patterns C may be formed to have vertical sidewalls.

Embodiments of the present invention describe the method for forming the conductive patterns with the first and second patterns. However this embodiment is not restrictive but illustrative. Thus, this invention can be applied to other methods for forming conductive patterns by etching the conductive layer several times.

Furthermore, embodiments of the present invention can be applied to other methods for forming the metal line, the gate line, and the bit line or a method for forming patterns including the conductive layer. Particularly, embodiments of the present invention can be applied to a method for forming metal lines in a nonvolatile memory device. Hereinafter, a method for forming the metal line in accordance with embodiments of the present invention is briefly described.

An interlayer insulation layer is formed over a substrate with a lower structure. The interlayer insulation layer is selectively etched to form a contact hole. A conductive material fills the contact hole to form a contact plug.

A metal layer and a hard mask layer are sequentially formed over a resultant structure including the contact plug. Photoresist patterns are formed over the hard mask layer to form the metal line. Herein, preferably, the metal layer includes aluminum (Al).

The hard mask layer and the metal layer are etched to a predetermined thickness using the photoresist patterns as an etch barrier to form first patterns. Herein, the predetermined thickness ranges from approximately 30% to approximately 40% of a thickness of the metal layer.

Insulation layer spacers are formed on sidewalls of the first patterns. Herein, preferably, the insulation layer spacers include a material with a high selectivity ratio with the metal layer. The metal layer is etched using the insulation layer spacers as an etch barrier to form second patterns. Thus, the metal line is formed to include the first patterns with the spacers on the sidewalls thereof and the second patterns formed to be connected to a lower portion of the first patterns, respectively.

Herein, the specific process and condition for forming the metal line are the same as those illustrated in FIGS. 3A to 3C.

In embodiments of the present invention, to form the conductive patterns, the second patterns are formed using the spacers on the sidewalls of the first patterns. Thus, the conductive patterns with the vertical sidewalls can be formed.

As a result, the sidewalls of the conductive patterns are not damaged, and lean and collapse of the conductive patterns are prevented. Furthermore, characteristics of the semiconductor device are improved and a yield of the fabrication process can be increased.

While the present invention has been described with respect to specific embodiments, the above embodiments of the present invention are not limitative but illustrative. It will be obvious to those skilled in the art that various changes and modifications may be made without departing from the spirit and scope of the invention as defined in the following claims.

What is claimed is:

1. A method for fabricating conductive patterns, the method comprising:
forming a conductive layer over a substrate;
etching the conductive layer to a first thickness to form first patterns;
forming spacers on sidewalls of the first patterns; and
etching the conductive layer to a second thickness using the spacers as an etch barrier to form second patterns.

2. The method of claim 1, wherein the conductive patterns including the first patterns and the second patterns have vertical sidewalls.

3. The method of claim 2, wherein the conductive patterns comprise a metal line, a gate line, or a bit line.

4. The method of claim 1, further comprising forming a hard mask layer over the conductive layer after forming the conductive layer,
wherein the first patterns comprise a stack structure of conductive patterns and hard mask patterns.

5. The method of claim 4, wherein the spacers include a material having a high selectivity ratio with the hard mask layer.

6. The method of claim 1, wherein the spacers include a material having a high selectivity ratio with the conductive layer.

7. The method of claim 4, wherein the hard mask layer includes a nitride layer and the spacers include an oxide layer or a nitride layer.

8. The method of claim 1, wherein the first thickness ranges approximately 30% to approximately 40% of a thickness of the conductive layer.

9. A method for fabricating a semiconductor device, the method comprising:
forming a metal layer over a substrate;
etching the metal layer to a first thickness using mask patterns as an etch barrier to form first patterns;
forming insulation layer spacers on sidewalls of the first patterns; and
etching the metal layer to a second thickness using the mask patterns and the insulation layer spacers as etch barriers to form second patterns.

10. The method of claim 9, wherein a metal line comprising the first and the second patterns has vertical sidewalls.

11. The method of claim 9, wherein the first thickness ranges from approximately 30% to approximately 40% of a thickness of the metal layer.

12. The method of claim 10, wherein the metal layer comprises aluminum (Al), tungsten (W), or copper (Cu).

13. A semiconductor device, comprising:
conductive patterns comprising:
first patterns with spacers formed on sidewalls thereof; and
second patterns each formed to be connected to a lower portion of the corresponding first pattern,
wherein the spacers are used as etch barriers when the second patterns are formed.

14. The semiconductor device of claim 13, wherein the spacers include a material having a high selectivity ratio with a conductive layer used to form the conductive patterns.

15. The semiconductor device of claim 13, wherein the conductive patterns comprise metal lines, gate lines, or bit lines.

16. The semiconductor device of claim 13, wherein the conductive patterns comprise metal lines in a nonvolatile memory device.
